(19) United States
(12) Patent Application Publication
(10) Pub. No.: US 2005/0206370 A1
(43) Pub. Date: Sep. 22, 2005

(54) Labeling a portable data storage device storing a collection of image data

(76) Inventors: Alfred I-Tsung Pan, Sunnyvale, CA (US); Steven Rosenberg, Palo Alto, CA (US); Maaike L. Evers, San Francisco, CA (US); Jeffrey L. Smith, San Mateo, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/805,019

(22) Filed: Mar. 19, 2004

(51) Int. Cl. G01R 33/00; G01B 7/14

(52) U.S. Cl. 324/200; 324/207.16

(57) ABSTRACT

Schemes for labeling a portable data storage device storing a collection of image data are described. In one aspect, an image processing apparatus includes a port, a label composer, and a print module. The port may be configured to receive a portable data storage device having a memory configured to store a collection of image data and a digital label including a plurality of display elements each capable of presenting one of at least two possible colors. The label composer may be operable to select at least one image in a collection of image data being stored in the memory of a portable data storage device received in the port as representative of the image data collection. The print module may be coupled to the port and the label composer. The print module may be operable to selectively configure the display elements in the digital label of the portable data storage device received in the port to print at least one image respectively corresponding to the at least one representative image selected by the label composer.

### BACKGROUND

A wide variety of different portable data storage devices are available for storing a collection of image data. For example, analog and digital camcorders respectively store video image data on analog and digital tape media contained within individual cassettes. Digital cameras and other portable electronic devices that are equipped with image sensors store digital still image data and, in some implementations, digital video image data on portable memory cards, such as secure digital (SD) memory cards and multimedia cards (MMCs). In computing environments, image data also are stored in portable computer memory devices, such as floppy disks, compact discs (CDs), digital video discs (DVDs), and the like.

Individuals and organizations are accumulating large collections of image data. Oftentimes, these collections are stored in respective collections of portable data storage devices. As these collections grow in number and diversity, individuals and organizations increasingly require systems and methods for organizing and browsing these physical collections of portable data storage devices.

Various approaches have been proposed for labeling portable data storage devices with information that conveys information about the contents stored on these devices. Adhesive labels with brief handwritten notes (e.g., dates, titles, and brief descriptions) typically are used to label portable data storage devices. Recently, there have been proposals to use rewritable electronic displays to label portable data storage devices.

In one approach, a liquid crystal display (LCD) is used to label a floppy computer disk. In this approach, a modified floppy disk drive controls the LCD to automatically label the floppy disk with the filenames being copied to or deleted from the floppy disk. In other approaches, electronic paper is used to label floppy computer disks, CDs, and video cassettes. In these approaches, alphanumeric title data or directory data relating to files stored on the storage device is printed on electronic paper that is attached to a surface of the storage device.

Electronic paper is a display system that retains images with little or no power. Images typically are generated on an electronic paper medium by selectively applying an electric field to switchable display elements (e.g., dichroic spheres) in localized regions of the medium. In a typical implementation, an electrically conductive backplane electrode is placed behind the electronic paper medium and a second electrically conductive front plane electrode is placed in front of the electronic paper medium. Applying an electric field of one polarity to the medium switches the display elements to one orientation (e.g., black-side-up), and reversing the polarity of the applied electric field switches the display elements to a second orientation (e.g., white-side-up). The electronic paper medium remains in the switched (or “printed”) state after the electric field is removed until a new electric field is applied to change the orientation of the is display elements.

### SUMMARY

In one aspect, the invention features an image processing apparatus that includes a port, a label composer, and a print module. The port is configured to receive a portable data storage device having a memory configured to store a collection of image data and a digital label including a plurality of display elements each capable of presenting one of at least two possible colors. The label composer is operable to select at least one image in a collection of image data being stored in the memory of a portable data storage device received in the port as representative of the image data collection. The print module is coupled to the port and the label composer. The print module is operable to selectively configure the display elements in the digital label of the portable data storage device received in the port to print at least one image respectively corresponding to the at least one representative image selected by the label composer.

The invention may also feature a machine-implemented image processing method in accordance with which at least one image in a collection of image data being stored in a portable data storage device is selected as representative of the image data collection. The portable data storage device has a memory configured to store the collection of image data and a digital label including a plurality of switchable display elements each capable of presenting one of at least two possible colors. The display elements in the digital label of the portable data storage device are selectively oriented to print at least one image respectively corresponding to the at least one selected representative image.

The invention features an image processing apparatus configured to implement the image processing method described above and a machine-readable medium storing machine-readable instructions for causing a machine to implement the image processing method described above.

In another aspect, the invention features a data storage system that includes a memory, a digital label, a label composer, a label adapter, and a portable housing. The memory is configured to store a collection of image data. The digital label includes a plurality of display elements each capable of presenting one of at least two possible colors. The label composer is operable to select an image in a collection of image data stored in the memory as an image representative of the image data collection. The label adapter is coupled to the digital label and is operable to selectively configure the display elements in the digital label to present at least one image corresponding to the representative image selected by the label composer. The portable housing is configured to plug into a port of an external device. The portable housing contains the memory and the label adapter, and has a surface supporting the digital label.

Other features and advantages of the invention will become apparent from the following description, including the drawings and the claims.

### DESCRIPTION OF DRAWINGS

FIG. 1 is a diagrammatic cross-sectional side view of an implementation of a digital label in accordance with embodiments of the invention.

FIGS. 2A-2A are diagrammatic views of respective image processing apparatus and associated portable data storage devices in accordance with embodiments of the invention.

FIG. 3 is a block diagram of an implementation of a subsystem of an image processing apparatus in accordance with embodiments of the invention.

FIG. 4 is a diagrammatic view of an implementation of a print head printing on digital label carried by a portable data storage disc in accordance with embodiments of the invention.

FIG. 5 is a diagrammatic front view of an implementation of a portable data storage device that includes a digital label showing an image representative of a collection of image data stored in a memory of the portable data storage device in accordance with embodiments of the invention.

FIG. 6 is a flow diagram of an implementation of a method of labeling a portable data storage device in accordance with embodiments of the invention.

FIG. 7 is a flow diagram of an implementation of a method of selecting an image in a data collection being stored in a portable data storage device as a representative image for the image data collection in accordance with embodiments of the invention.

FIG. 8 is a flow diagram of an implementation of a method of selecting an image in a data collection being stored in a portable data storage device as a representative image for the image data collection in accordance with embodiments of the invention.

FIGS. 9A and 9B are diagrammatic views of implementations of user interfaces for presenting for selection by a user images corresponding to a collection of image data being stored in the memory of a portable data storage device in accordance with embodiments of the invention.

FIGS. 10A and 10B are front and back views of an implementation of a portable data storage device that is configured to present for selection by a user images corresponding to a collection of image data being stored in the memory of a portable data storage device in accordance with embodiments of the invention.

FIG. 11 is a diagrammatic view of an implementation of a portable data storage system that includes a portable data storage device plugged into an external power source module in accordance with embodiments of the invention.

### DETAILED DESCRIPTION

In the following description, like reference numbers are used to identify like elements. Furthermore, the drawings are intended to illustrate major features of exemplary embodiments in a diagrammatic manner. The drawings are not intended to depict every feature of actual embodiments nor relative dimensions of the depicted elements, and are not drawn to scale.

Multiple embodiments for labeling portable data storage devices storing collections of image data are described in detail below. The image data may correspond to one or both of still image data or video image data. In general, a portable data storage device is labeled with an image in a collection of image data being stored in a memory of the portable data storage device that is selected as being representative of the image data collection. The expression “being stored” refers to image data that currently is stored in the portable data storage device memory or is slated to be stored in the portable data storage device memory. Thus, the representative image may be selected before or after the representative image is stored in the portable data storage device memory. For example, in some implementations, the image data in a collection to be stored and at least one representative image first are selected and then stored in a portable data storage device.

The portable data storage device is labeled with a “digital label”, which refers to any display medium may be “printed on” by applying an electric filed, an electric current, or a magnetic field. Exemplary types of digital labels include electrically writable displays and liquid crystal displays. An electrically writable displays may include any type of medium that has localized regions with display elements that are switchable to produce visible content (e.g., an image containing one or more of pictures, graphics, and text). Exemplary switchable display elements include bi-stable, dual-color microcapsules, dichroic spheres, and optically anisotropic colorant particles.

Labeling a portable data storage device with an image representative of the collection of image data stored in the device provides a user with a context-sensitive label that readily conveys the contents of the portable data storage device. For example, a user readily will know that the portable data storage device contains the sill image or video image data corresponding to the representative image. In addition, the user either will recall what other image data was stored on the portable data storage device along with the representative image data or will be able to infer what other image data is stored. For example, when the portable data storage device contains image data captured by an imaging device, such as a still image camera or a video camcorder, a user will be able to infer that the other image data relates to scenes and events captured at or approximately the same time when the representative image data was captured.

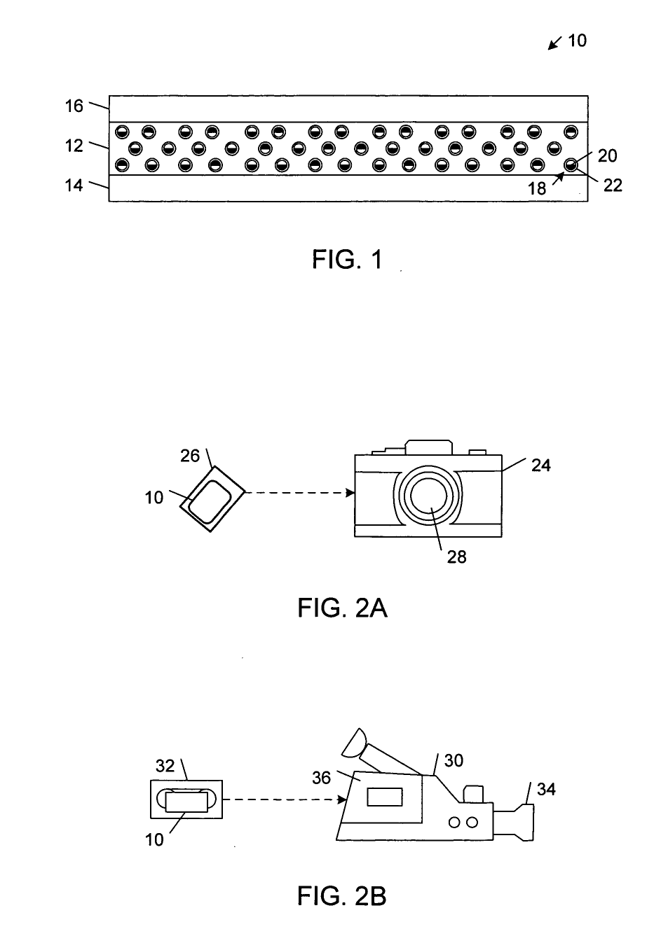

FIG. 1 shows an embodiment of a digital label 10 in the form of an electrically writable medium that includes at least one colorant layer 12 that is disposed between a pair of protective layers 14, 16. The colorant layer 12 is formed from a polymer binder and a plurality of switchable display elements that are implemented in the form of bi-stable, dual-color microcapsules 18. Each microcapsule 18 includes a solid bi-colored sphere 20 housed in a microencapsulating shell 22. Each microcapsule sphere 20 is coated with a lubricating fluid. Each sphere 20 is colored white on one hemisphere and colored black on the opposing hemisphere. The black colorant may be vapor-deposited, for example, on a solid white sphere that may be made of, for example, a pigmented glass, a polymer, or a ceramic. The vapor deposit contains charge species that give each of the spheres 20 an electric dipole for field alignment. The resulting charge on each bi-colored sphere allows the bi-colored spheres 20 to be oriented in accordance with an applied electric field so that each sphere 20 presents either the white hemisphere face or the black hemisphere face at the top surface of the electrically writable medium. The microcapsules 18 may be supported in a fixed polymer coating layer, while allowing each microcapsule sphere 20 to rotate within the microencapsulating shell 22. The electrically writable medium 10 preferably contains a sufficient density of microcapsules 18 so that the electrically writable medium 10 appears completely white or completely black when all of the microcapsules 18 are oriented in the same direction.

In general, protective layer 14 may be formed of any flexible, fibrous or non-fibrous sheet material. In some embodiments, the protective layer 14 of electrically writable medium 10 has the look and feel of paper, but has far greater durability than most, commonly-used cellulose fiber papers. Such media are known in the art, and commonly consist of polymeric impregnated papers or polymeric fibers woven or assembled into films that have a paper appearance. Examples of such papers include Tyvek® (available from E. I. du Pont de Nemours and Company of Wilmington, Del., U.S.A.) and a series of Master-Flex™ papers (available from Appleton Papers Inc. of Appleton, Wis., U.S.A.).

Top protective layer 16 is optional and may be coated over the colorant layer 12 to increase the durability of electrically writable medium 10. Protective layer 16 may be formed of a transparent polymer, such as PMMA (polymethylmethacrylate), or a blend of polymers. In some embodiments, the polymer binder and microcapsule shells 20 have matching refractive indices to minimize light scattering within the colorant layer 12, improving image contrast. The gloss of the electrically writable medium 10 may be controlled by the characteristics of the colorant layer 12 or the optional protective layer 16, or both. In some embodiments, the refractive indices of protective layer 16 and colorant layer 12 may be mismatched to enhance the “white paper” mode by inducing additional light scattering to enhance whiteness.

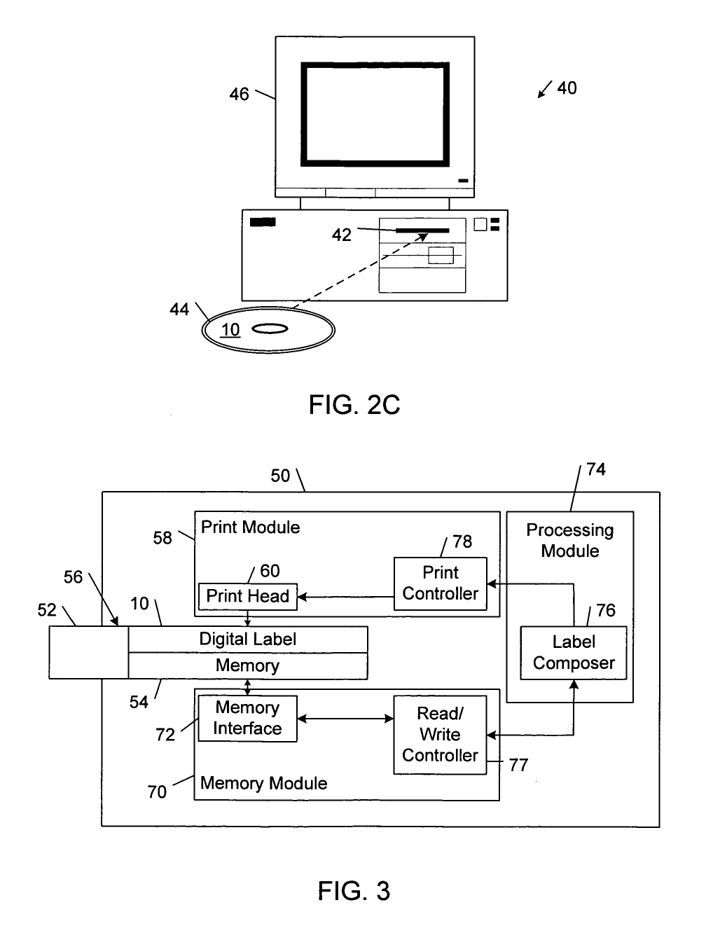

In general, digital label 10 may be disposed on any type of portable data storage device that is configured to store a collection of image data. FIGS. 2A-2A show exemplary types of image processing apparatus and associated portable data storage devices that may include digital label 10.

FIG. 2A shows a digital camera 24 and a portable data card 26 (e.g., a flash memory card, such as an SD card or a MMC). Digital camera 24 includes a lens 28, an image sensor, and a port configured to receive the portable data card 28. In some implementations, digital camera 24 is configured to store digital still image data and digital video data in the memory of portable data card 26.

FIG. 2B shows a digital video camcorder 30 and a portable data cassette 32 (e.g., a digital video DV cartridge or a MiniDV cartridge). Digital video camcorder 30 includes a lens 34, an image sensor, and a port 36 configured to receive the portable data cassette 36. In some implementations, digital video camcorder 30 is able to store digital still images in the portable cassette 32 or in a separate portable data card (e.g., a flash memory card, such as an SD card or a MMC).

FIG. 2C shows a computer system 40 that includes a port 42 for receiving a portable optical data disk 44 (e.g., a CD or DVD based storage medium). Computer system 40 includes a processing unit, a system memory, and a system bus that couples processing unit to the various components of computer system 40. The processing unit may include one or more processors, each of which may be in the form of any one of various commercially available processors. The system memory may include a read only memory (ROM) that stores a basic input/output system (BIOS) containing start-up routines for computer system 40 and a random access memory (RAM). The system bus may be a memory bus, a peripheral bus or a local bus, and may be compatible with any of a variety of bus protocols, including PCI, VESA, Microchannel, ISA, and EISA. Computer system 40 also may include one or more persistent storage memory components (e.g., a hard drive, a floppy drive, a CD ROM drive, magnetic tape drives, flash memory devices, and digital video discs) that are connected to the system bus and contain one or more computer-readable media disks that provide non-volatile or persistent storage for data, data structures and computer-executable instructions. A user may interact (e.g., enter commands or data) with the computer system 40 using one or more input devices (e.g., a keyboard, a computer mouse, a microphone, joystick, and touch pad). Information may be presented through a graphical user interface (GUI) that is displayed to the user on a display monitor 46, which is controlled by a display controller of computer system 40. Computer system 40 also may include peripheral output devices, such as speakers and a printer. One or more remote computers may be connected to computer system 40 through a network interface card (NIC).

FIG. 3 shows an embodiment of a subsystem 50 that may be incorporated into any of the above-described image processing apparatus to provide functionality for printing on a digital label 10, which is disposed on a portable data storage device 52, and for reading data from and storing data in a memory 54 of portable data storage device 52. Portable data storage device 52 may be implemented in the form of any self-contained portable memory device form factor, including a card (e.g., a Smart Card or magnetic swipe card), a circular disc (e.g., a DVD or CD), or a rectangular disk (e.g., memory card, a 3.5 inch floppy disk, or a ZIP Drive disk). Memory 54 may include any type of non-volatile memory, including, for example, semiconductor memory devices, such as EPROM, EEPROM, and flash memory devices; magnetic memory devices, such as removable hard disks; magneto-optical disks; and optical disks, such as DVD-ROM, DVD-RAM, CD-ROM, and CD-RAM.

Subsystem 50 includes a port 56 that is configured to receive the portable data storage device 52. In some implementations, port 56 includes a holder (e.g., a slot or a tray) that is configured to receive portable data storage device 52 and hold portable data storage device 52 while data is being written to memory 54 and while content is being printed on digital label 10.

Subsystem 50 includes a print module 58 with a print head 60 that is operable to print on the digital label 10 that is carried by portable data storage device 52. The particular implementation of print head 60 depends on the particular implementation of digital label 10. In general, print head 60 may be any form of print head that is capable of printing on digital label 10 by electrically reorienting switchable display elements in the medium. In some embodiments, print head 60 also is operable to selectively erase regions of digital label 10.

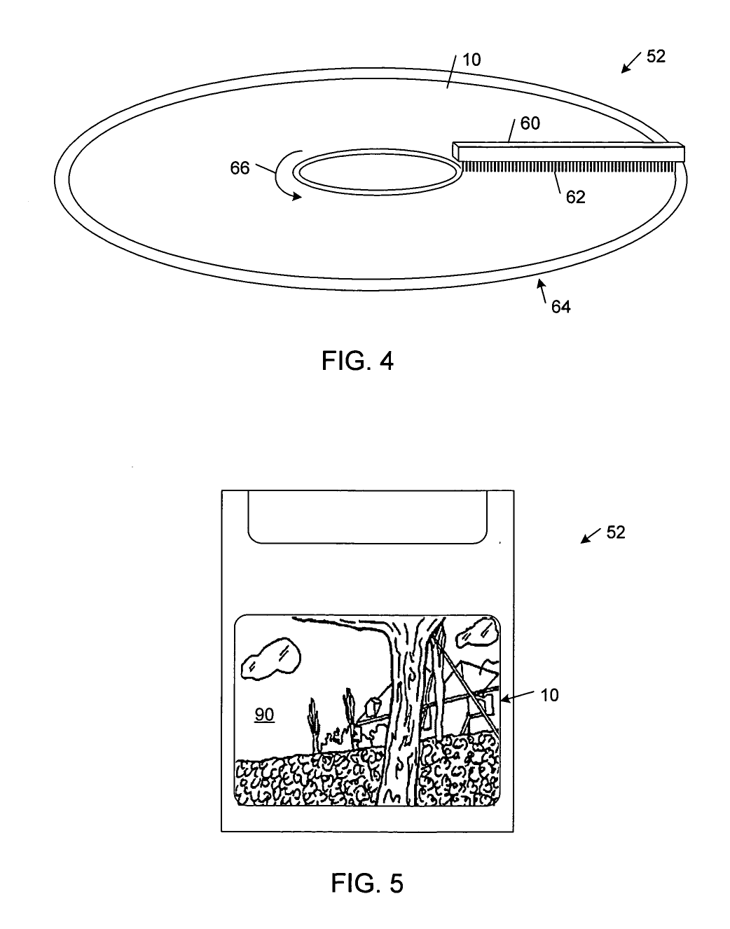

FIG. 4 shows an exemplary embodiment of a print head 60 that includes a linear array of electrodes 62 that are operable to simultaneously print on multiple localized areas along a linear path across the surface of digital label 10, which is carried on a disc-shaped portable data storage device 52. Portable data storage device 52 may include an optical storage medium 64 (e.g., a CD or DVD based storage medium) on the side of portable data storage device 52 that is opposite the side carrying digital label 10. In one implementation, portable data storage device 52 spins within holder 56 of subsystem 50 in a direction indicated by arrow 66. While device 52 spins, print head 60 may print on digital label 10. In another implementation, print head 60 is scanned across the surface of digital label 10 during printing.

In some implementations, print head 60 includes a two-dimensional addressing array that includes multiple independently addressable electrodes for simultaneously printing on localized areas of the digital label 10 by selective application of electric fields to the medium that are sufficient to reorient switchable display elements in the medium.

Referring back to FIG. 3, subsystem 50 includes a memory module 70 that has a memory interface 72 that is constructed and arranged to write data to the memory 54 of portable data storage device 52. The particular implementation of memory interface 72 depends on the particular implementation of memory 54. For example, in some application environments (e.g., CD or DVD based memory environments), the memory interface 72 includes an electromechanical data head configured to write data to memory 54. In other application environments (e.g., smart card based memory environments), the memory interface 72 includes a connector that delivers electronic instructions to a mated connector of memory 54. In some implementations, memory interface 72 is operable to read data from memory 54 of portable data storage device 52.

Subsystem 50 also includes a processing module 74 that includes a label composer 76, which is operable to select at least one image in a collection of image data being stored in the memory 54 as representative of the image data collection. Processing module 74 may include one or more processors, each of which may be in the form of any one of various commercially available processors. Processing module 74 interfaces with memory interface 72 through a read/write controller 77 and interfaces with print head 60 through a print controller 78.

In general, the label composer 76, the print controller 78, and the read/write controller 76 are not limited to any particular hardware or software configuration, but rather they may be implemented in any computing or processing environment, including in digital electronic circuitry or in computer hardware, firmware, device driver, or software. The modules 58, 70, and 74 of subsystem 10 may be embedded in the hardware of any one of a wide variety of electronic devices, including digital cameras, digital camcorders, printers, computers, and other electronic devices, such as mobile phones and personal digital assistants.

Some dual-mode implementations of subsystem 50 include a digital label detector that is operable to detect whether or not a portable data storage device received by port 56 includes a digital label. The digital label detector may include, for example, a test electrode that applies a bias to mark (e.g., produce a discernable color change in a localized region) the surface of a portable data storage device that is loaded into port 56. A sensor (e.g., a photodetector) then detects whether the applied bias produced a test mark on the surface of the portable data storage device, in which case the sensor produces a signal that indicates that the digital label is present.

Some embodiments also may include, upstream of print head 60, an erasing station that includes, for example, a charged-electrode that is biased to orient all of the switchable display elements of an electrically writable medium in the same direction (e.g., white sides facing up) before visible content is printed on the electrically writable medium.

FIG. 5 shows an exemplary implementation of a flash memory type of portable data storage device 52 that includes a surface supporting a digital label 10 presenting an image 90 selected from a collection of image data stored on device 52 as representative of the image data collection. The representative image 90 appearing on digital label 10 may be an exact copy of the corresponding image in the collection or it may be a modified version of the corresponding image in the collection. For example, in some implementations, the representative image 90 corresponds to a reduced-resolution thumbnail of the corresponding image in the collection.

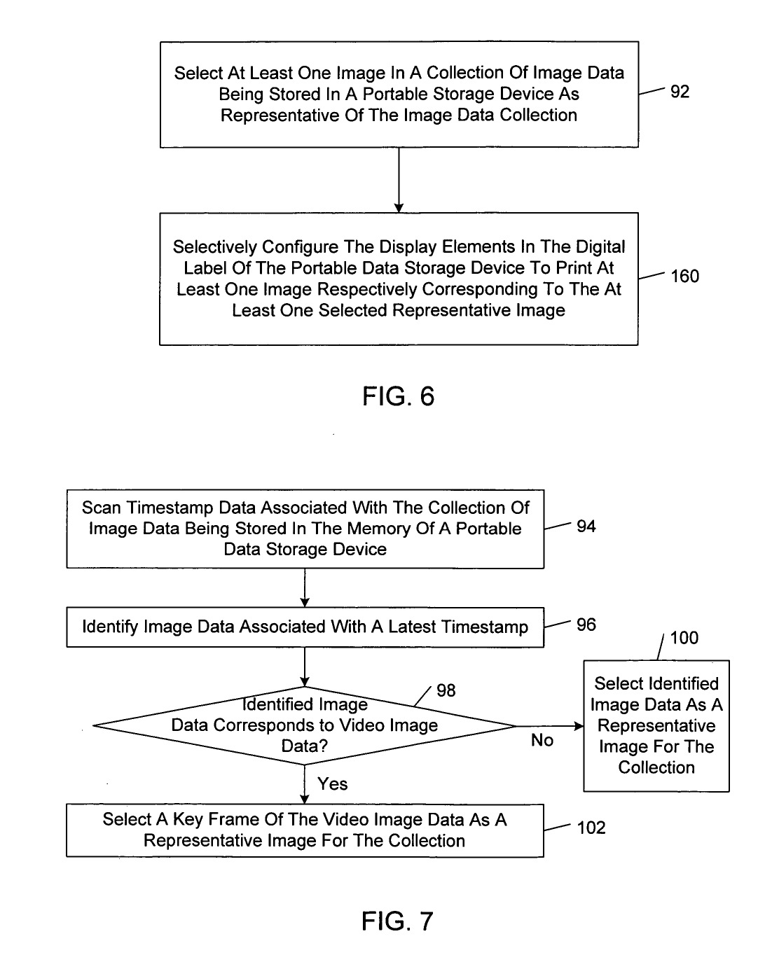

Referring to FIGS. 6, 7 and 8, and initially to FIG. 6, in some embodiments, a portable data storage device 52 is labeled as follows.

The label composer 76 selects at least one image in a collection of image data being stored in the portable data storage device as representative of the image data collection (step 92). As explained in detail below, the label composer 76 may select the representative image 90 automatically or based on user input.

FIG. 7 shows an exemplary embodiment of a method by which label composer 76 automatically selects the representative image 90. In general, label composer 76 may automatically select the representative image 90 based on properties associated with the image data being stored on the portable data storage device. In the illustrated embodiment, label composer scans timestamp data associated with the collection of image data (step 94). Label composer 76 identifies the image data associated with the latest timestamp (step 96). If the identified image data does not correspond to video image data (step 98), the label composer 76 selects the identified image data as a representative image for the collection (step 100). If the identified image data does correspond to video image data (step 98), the label composer 76 selects a key frame of the video image data as a representative image for the collection (step 102). The selected key frame may correspond to the key frame of the identified video data with the latest timestamp or it may be selected based on some other criterion.

Any standard video processing or video summarizing technique may be used to identify one or more keyframes in video image data. For example, a key frame may correspond to an image frame at the beginning of a video clip (or file) or at the beginning of a shot (i.e., a sequence of video frames distinguished from other video frame sequences by a detectable scene change or other transition) within a video clip. In some implementations a key frame may correspond to the first image frame in which a person is detected. The key frames of a video file may be stored with the associated video image file (e.g., in the header of the video image file) or the label composer 76 or some other module of the image processing system may be configured to identify key frames in the video file.

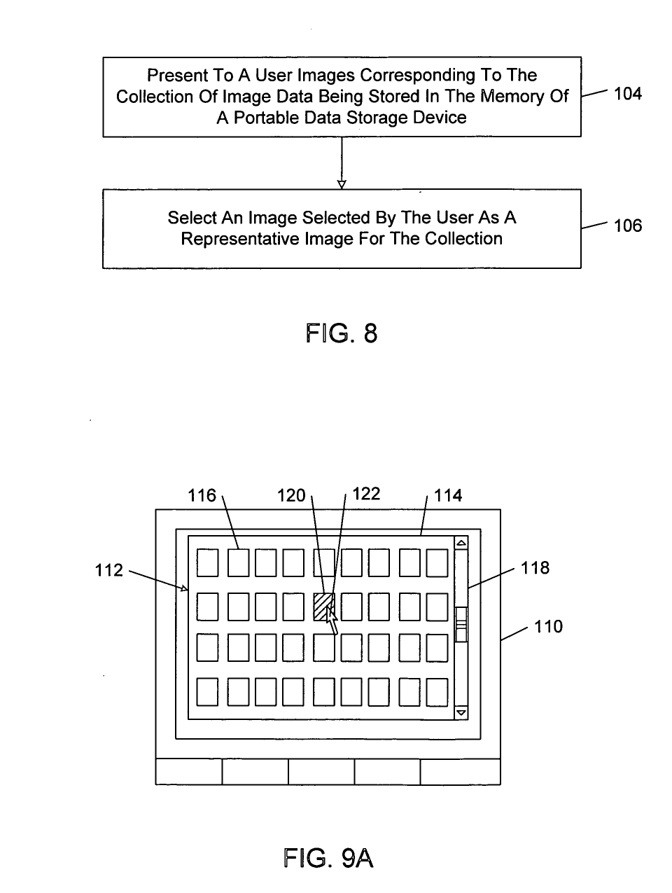

FIG. 8 shows an exemplary embodiment of a method by which label composer 76 selects the representative image 90 based on user input. Label composer 76 presents to the user images corresponding to the collection of image data being stored in the memory of a portable data storage device (step 104). Depending on the application environment, the images may be presented to the user on a display screen (e.g., a computer monitor, or a display of a portable electronic device, such as a digital camera, a cellular telephone, or a personal digital assistant) or on the digital label 10. After images corresponding to the image data collection are presented to the user, the label composer 76 selected the at least one image selected by the user as the representative image or images for the collection (step 106).

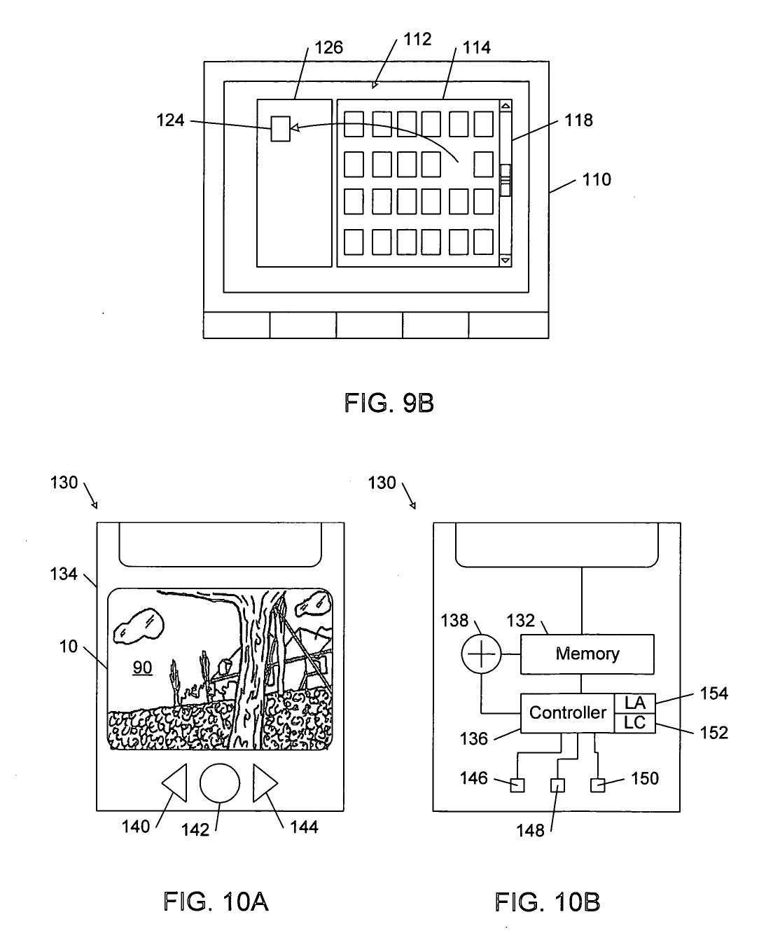

Referring to FIGS. 9A and 9B, in some implementations, the label composer 76 presents the images corresponding to the image data collection on a display screen 110. The display screen 110 displays a graphical user interface 112 that includes an image collection display area 114. Image collection display area 114 may be implemented as a conventional computer graphics window. Image collection display area 114 is operable to display symbols 116 that are representative of images in the collection. Symbols 116 may be implemented as any graphical symbols that identify the image data respectively associated with the symbols. For example, in some implementations, image and video data are represented by thumbnail image symbols corresponding to reduced-resolution versions of the corresponding image data. Image collection display area 114 includes a scrollbar 118 that enables a user to scroll the viewable portion of image collection display area 114 through the collection of image data being stored on the portable data storage device. In the embodiment illustrated in FIG. 9A, a user may select an image 120 corresponding to the representative image 90 with a pointing device 122. In the embodiment illustrated in FIG. 9B, a user may select an image 124 corresponding to the representative image 90 by dragging the image 124 from the image collection area to a separate representative image area 126. Other methods of allowing a user to designate images as representative images also may be used.

The graphical user interface 112 may include one or more buttons that allow a user to control how symbols are presented, including buttons that play, stop, and pause a slideshow presentation of the symbols 116, buttons that allow the user to sort the symbols in various ways (e.g., chronologically and reverse-chronologically), and one or more special effect buttons, such as buttons that control zoom-in and zoom-out effects.

FIGS. 10A and 10B respectively show front and back views of an embodiment of a portable data storage device 130 that is configured to present for selection by a user images corresponding to the image data stored in a memory 132 of the portable data storage device 130. The portable data storage device 130 includes a rigid housing 134 containing the memory 132, a controller 136, a power supply 138 (e.g., a battery), user input buttons 140, 142, 144 that are connected to the controller 136 through respective input connections 146, 148, 150, and a display area supporting digital label 10. The controller 136 incorporates a label composer (LC) 152 and a label adapter (LA) 154.

The label composer 152 selects an image in a collection of image data stored in memory 132 as an image 90 representative of the image data collection. In some implementations, the label composer 152 automatically selects the representative image 90 based on a predetermined image selection rule (e.g., select the image data associated with the latest timestamp). In some embodiments, the label composer selects the representative image 90 based on user input received through one or more of the buttons 140-144. For example, in some implementations, the user may suspend the default automatic representative image selection process implemented by label composer 152 so as to keep a currently presented image displayed in the display area as the representative image until the user re-activates the default automatic representative image selection process. In some implementations, the user may scroll forwards or backwards through the images stored in memory 132 by depressing buttons 144, 140, respectively. In these implementations, the images in the collection may be presented in chronological or reverse-chronological order based on associated timestamp data in response to a single activation of the forward and reverse buttons 144, 140. The user may select the representative image by depressing the select/stop button 142 when an image corresponding to the representative image is displayed in the display area. In other implementations, the label composer 152 presents a new image in the display area each time the user depresses one of the forward and reverse buttons 144, 140. In these implementations, the representative image 90 corresponds to the image that is displayed after the user stops depressing the forward and reverse buttons 144, 140.

The label adapter 154 selectively configures the display elements in the digital label to present at least one image corresponding to the at least one image selected by the label composer. The particular implementation of the label adapter 154 depends on the nature of digital label 10. In some implementations, the digital label 10 corresponds to an electrically writable medium as described above, in which case the label adapter 154 is operable to selectively apply electric fields to the digital label to orient the display elements of the digital label 10 to produce the selected representative image. In other embodiments, the digital label 10 corresponds to an LCD-type of display medium, in which case the label adapter 154 is configured as a standard LCD adapter that is configured to generate control signals for producing the selected representative image on the LCD digital label.

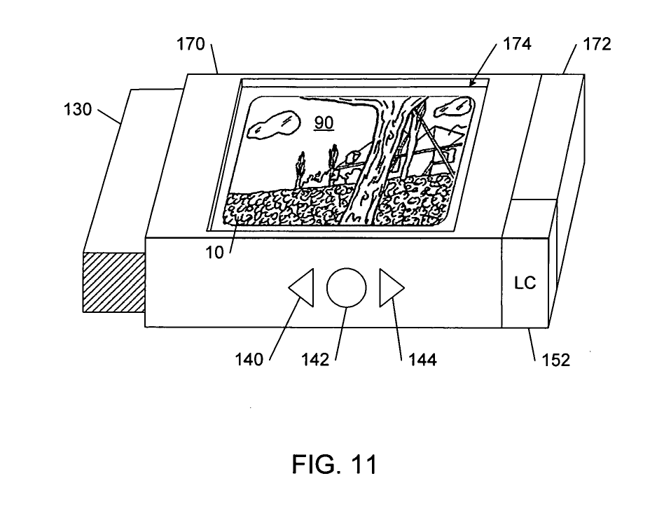

Referring to FIG. 11, in some implementations, the portable data storage device 130 does not include power supply 138. In these implementations, power for browsing the images stored in memory 132 and selecting the representative image 90 is provided externally. In the implementation of FIG. 11, the external power is supplied by a separately powered housing module 170 into which the portable data storage device 130 may be plugged. The housing module 170 includes a power source 172 (e.g., a battery) and a window 174 through which the digital label 10 on the portable data storage device 130 may be viewed. In another implementation, the external power is supplied by a cable that connects the portable data storage device 130 to an external power source (e.g., a computer). In some of these implementations, the control buttons 140-144 and the label composer 152 also may be located on the external power source, as shown in FIG. 11.

Referring back to FIG. 6, after the label composer has selected the representative image 90 (step 92), the print head 60 in the embodiment shown in FIG. 3 or the label adapter 154 in the embodiment shown in FIGS. 10A and 10B selectively configures the display elements in the digital label 10 to print at least one image respectively corresponding to the at least one representative image selected by the label composer 76, 152 (step 160). In the embodiment of FIG. 3, the print head 60 selectively orients the display elements in the digital label to print the one or more representative images. In the embodiment of FIGS. 10A and 10B, the label adapter 154 drives the pixels in the LCD-type of digital label 10 to display the one or more representative images.

Although systems and methods have been described herein in the context of particular machine and computing environments, these systems and methods are not limited to any particular hardware or software configuration, but rather they may be implemented in any computing or processing environment, including in digital electronic circuitry or in computer hardware, firmware or software.

1. An image processing apparatus, comprising:
a port configured to receive a portable data storage device having a memory configured to store a collection of image data and a digital label including a plurality of display elements each capable of presenting one of at least two possible colors;
a label composer operable to select at least one image in a collection of image data being stored in the memory of a portable data storage device received in the port as representative of the image data collection; and
a print module coupled to the port and the label composer and operable to selectively configure the display elements in the digital label of the portable data storage device received in the port to print at least one image respectively corresponding to the at least one representative image selected by the label composer.

2. The apparatus of claim 1, wherein the label composer is operable to drive the print module to print a reduced-resolution image of a higher resolution image being stored in the memory of the portable data storage device received in the port.

3. The apparatus of claim 1, wherein the label composer selects the at least one representative image based on time stamp data associated with the collection of image data being stored in the memory of a portable data storage device received in the port.

4. The apparatus of claim 1, further comprising a user interface configured to present to a user images corresponding to the collection of image data being stored in the memory of the portable data storage device received in the port.

5. The apparatus of claim 4, wherein the user interface is configured to present for selection by the user a sequence of images corresponding to the image data being stored in the memory of the portable data storage device received in the port.

6. The apparatus of claim 1, wherein the label composer is operable to select the at least one representative image before image data is stored in the memory of the portable data storage device received in the port.

7. The apparatus of claim 1, wherein the label composer is operable to select the at least one representative image after image data has been stored in the memory of the portable data storage device received in the port.

8. The apparatus of claim 1, further comprising an optical lens and an image sensor for capturing images received through the optical lens.

9. A machine-implemented image processing method, comprising:
selecting at least one image in a collection of image data being stored in a portable data storage device as representative of the image data collection, the portable data storage device having a memory configured to store the collection of image data and a digital label including a plurality of switchable display elements each capable of presenting one of at least two possible colors; and
selectively orienting the display elements in the digital label of the portable data storage device to print at least one image respectively corresponding to the at least one selected representative image.

10. The method of claim 9, further comprising printing on the digital label a reduced-resolution image of a higher resolution image being stored in the memory of the portable data storage device.

11. The method of claim 9, wherein the at least one representative image is selected based on time stamp data associated with the collection of image data being stored in the memory of the portable data storage device.

12. The method of claim 9, further comprising presenting to a user images corresponding to the collection of image data being stored in the memory of the portable data storage device.

13. The method of claim 12, wherein a sequence of images corresponding to the image data being stored in the memory of the portable data storage device is presented for selection by the user.

14. An image processing apparatus, comprising:
means for selecting at least one image in a collection of image data being stored in a portable data storage device as representative of the image data collection, the portable data storage device having a memory configured to store the collection of image data and a digital label including a plurality of switchable display elements each capable of presenting one of at least two possible colors; and
means for selectively orienting the display elements in the digital label of the portable data storage device to print at least one image respectively corresponding to the at least one selected representative image.

15. The apparatus of claim 14, further comprising means for printing on the digital label a reduced-resolution thumbnail of an image being stored in the memory of the portable data storage device.

16. The apparatus of claim 14, further comprising means for presenting to a user images corresponding to the collection of image data being stored in the memory of the portable data storage device.

17. A machine-readable medium storing machine-readable instructions for causing a machine to:
select at least one image in a collection of image data being stored in a portable storage data device as representative of the image data collection, the portable data storage device having a memory configured to store the collection of image data and a digital label including a plurality of switchable display elements each capable of presenting one of at least two possible colors; and
selectively orient the display elements in the digital label of the portable data storage device to print at least one image respectively corresponding to the at least one selected representative image.

18. The medium of claim 17, further comprising machine-readable instructions for causing the machine to print on the digital label a reduced-resolution thumbnail of an image being stored in the memory of the portable data storage device.

19. The medium of claim 9, further comprising machine-readable instructions for causing the machine to present to a user images corresponding to the collection of image data being stored in the memory of the portable data storage device.

20. A data storage system, comprising:
a memory configured to store a collection of image data;
a digital label including a plurality of display elements each capable of presenting one of at least two possible colors;
a label composer operable to select an image in a collection of image data stored in the memory as an image representative of the image data collection;
a label adapter coupled to the digital label and operable to selectively configure the display elements in the digital label to present at least one image corresponding to the representative image selected by the label composer; and
a portable housing configured to plug into a port of an external device, the portable housing containing the memory and the label adapter, and having a surface supporting the digital label.

21. The system of claim 20, wherein the label composer is operable to drive the label adapter to present on the digital label a reduced-resolution thumbnail of an image stored in the memory.

22. The system of claim 20, wherein the label composer selects the at least one representative image based on time stamp data associated with the collection of image data stored in the memory.

23. The system of claim 22, wherein the label composer selects as a representative image an image corresponding to image data in the collection associated with a latest time stamp.

24. The system of claim 22, wherein the label composer selects the at least one representative image based on user input.

25. The system of claim 24, wherein the label adapter is configured to present on the digital label images corresponding to images in the image data collection stored in the memory.

26. The system of claim 25, further comprising a user input, wherein the label composer selects an image selected by the user through the user input as a representative image.

27. The system of claim 26, wherein the label adapter is configured to present for selection by the user a sequence of images corresponding to the image data stored in the memory.

28. The system of claim 27, wherein the sequence of images presented by the label adapter is ordered in accordance with time stamp data associated with the image data stored in the memory.

29. The system of claim 20, wherein the housing contains the label composer.

30. The system of claim 20, further comprising an external power source comprising a housing configured to connect to the portable housing and containing a power supply and the label composer.
